(19) United States
(12) Patent Application Publication
(10) Pub. No.: US 2012/0287958 A1
(43) Pub. Date: Nov. 15, 2012

(54) Laser Diode Assembly and Method for Producing a Laser Diode Assembly

(76) Inventors: Alfred Lell, Maxhütte-Haidhof (DE); Martin Strassburg, Donaustauf (DE)

(21) Appl. No.: 13/515,226

(22) PCT Filed: Nov. 11, 2010
(86) PCT No.: PCT/EP2010/067271

§ 371 Date: Jun. 11, 2012

(30) Foreign Application Priority Data
Dec. 11, 2009 (DE) 10 2009 054 564.6

(51) Int. Cl. H01S 5/22; H01L 33/08

(52) U.S. Cl. 372/45.01; 438/35; 257/E33.06

(57) ABSTRACT

A laser diode assembly comprising a semiconductor substrate; (2; 101; 201; 301; 72), at least two laser stacks (17, 18; 117, 118, 119; 217, 218; 317, 318; 97, 98, 99), each having one active zone; (6, 12; 105, 109, 113; 207, 213; 307, 311; 76, 82, 88), and at least one translucent ohmic contact (9; 107, 111; 204, 210; 304, 309; 79, 85), wherein the laser stacks (17, 18; 117, 118, 119; 217, 218; 317, 318; 97, 98, 99) and the translucent ohmic contact (9; 107, 111; 204, 210; 304, 309; 79, 85) are monolithically deposited on the semiconductor substrate (2; 101; 201; 301; 72), wherein the laser stacks (17, 18; 117, 118, 119; 217, 218; 317, 318; 97, 98, 99) are electrically connected by the translucent ohmic contact (9; 107, 111; 204, 210; 304, 309; 79, 85), and wherein laser diodes (26a, 26b, 27a, 27b; 36a, 36b, 37a, 37b; 46a, 46b, 47a, 47b; 66a, 66b, 67a, 67b; 94a, 94b, 95a, 95b, 96a, 96b) that are formed from the laser stacks (17, 18; 117, 118, 119; 217, 218; 317, 318; 97, 98, 99) form a two-dimensional structure.

The present invention relates to a laser diode assembly which features a semiconductor substrate, comprising laser stacks and ohmic contacts between the laser stacks. A method for manufacturing a laser diode assembly is also specified.

Laser diodes as described in the prior art achieve power densities of approximately 40,000 kW/cm² and more. Use of such high power densities is associated with the risk of irreparable damage to the laser facet, also known as COD (catastrophic optical damage). Until now, the facet load limit has essentially been reduced by increasing the width of the light-emitting region or alternatively by arranging a plurality of light-emitting strips next to each other on a laser bar (so-called laser array).

In this case, it is often problematic that the one-dimensional widening of the emission surface results in a highly asymmetrical laser emission, which can only be focused using expensive lens systems if at all. Concentration to give a high optical output power is therefore no longer possible without restrictions. In addition, the spread of the laser emission significantly limits the optical projection characteristics.

The present invention addresses the problem of providing a laser diode assembly by means of which the above-described disadvantages are avoided completely or at least reduced.

This problem is solved by a laser diode assembly and a method for manufacturing a laser diode assembly in accordance with the independent claims 1 and 15 respectively.

Developments and advantageous embodiments of the laser diode assembly and the method for manufacturing a laser diode assembly are specified in the dependent claims.

### Exemplary embodiments

Various embodiments feature a laser diode assembly having a semiconductor substrate. At least two laser stacks, each comprising an active zone, are mounted on the semiconductor substrate. Translucent ohmic contacts for electrically connecting the laser stacks are also provided. The laser stacks and the translucent ohmic contact are monolithically deposited onto the semiconductor substrate. Laser diodes having a two-dimensional structure are formed from the laser stacks.

The semiconductor substrate can feature a III-V compound semiconductor material, in particular a nitride compound semiconductor material such as GaN.

The active zones can be pn transition zones, double heterostructures, multiple quantum well structures (MQW), or single quantum well structures (SQW). Quantum well structure means: quantum wells (3 dimensions), quantum wires (2 dimensions) and quantum dots (1 dimension).

The injection of current into the active region is effected by means of a p-doped layer and an n-doped layer.

As described above, the active zone can be a multiple quantum well structure. It consists of a plurality of active layers. A barrier layer is situated between the active layers in each case. In each case, a further barrier layer precedes the first active layer and succeeds the last active layer in the direction of growth. The active layers contain or consist of InGaN and are between approximately 0.8 nm and approximately 10 nm thick. The barrier layers between the quantum well structures contain or consist of AlₓIn_{y}Ga_{1-x-y}N (0≦x≦1; 0≦y≦1) and are between 1 and 20 nm thick.

The monolithic growth means that the plurality of laser stacks are deposited on the same wafer. In particular, laser bars are not attached one on top of the other by means of e.g. soldering or adhesion.

In the present invention, the layer sequences are deposited one on top of the other by means of molecular beam epitaxy or metallo-organic gas-phase epitaxy or gas-phase epitaxy or liquid-phase epitaxy.

The monolithic growth of the laser stacks is advantageous because particularly small gaps between the laser diodes can be realized in this way. Without monolithic growth, laser diode assemblies would be limited to a vertical minimal gap between the laser diodes of approximately 100 μm. This minimal gap is based on the minimal thickness (of the laser diode structures) that must be processed. This large gap between the vertically arranged laser diode structures limits the maximal achievable optical power density and also the spread.

In a particularly advantageous embodiment, the translucent ohmic contact is a surface-emitting laser emitter (VCSEL vertical-cavity surface-emitting laser). The translucent ohmic contact is unavoidable for lateral light propagation in a laser medium. The translucent ohmic contact has only slight optical absorption in the range of the laser wavelength. The laser radiation is advantageously only slightly attenuated before it leaves the laser diode assembly.

In a preferred embodiment of the laser diode assembly, the translucent ohmic contact features indium tin oxide (ITO). ITO is a semiconductive substance that is largely transparent in visible light. It is a composite oxide, comprising e.g. 90% indium(III) oxide (In2O3) and 10% tin(IV) oxide (SnO2).

In a preferred embodiment of the laser diode assembly, the translucent ohmic contacts can be realized as tunnel diodes by means of a monolithic process. The tunnel transition zone is also formed by deposition during the epitaxial growth of the laser structures. It is used for the electrical connection. The tunnel transition zone comprises two highly doped layers of different conduction types (n-type conduction and p-type conduction). The highly doped n-type layer has a doping of more than 5×10¹⁸ cm⁻³, preferably approximately 1×10¹⁹ cm⁻³, and particularly preferably more than 5×10¹⁹ cm ⁻³. The highly doped p-type layer has a doping of more than 1×10¹⁹ cm⁻³, preferably approximately 8×10¹⁹ cm⁻³, and particularly preferably more than 1.5×10²⁰ cm⁻³. These two layers are separated from each other by at least one preferably undoped intermediate layer of e.g. AlGaN. The laser diodes are electrically connected in series by the tunnel transition zones. The tunnel transition zone or tunnel transition zones represent particularly weak potential barriers. This allows the tunneling of charge carriers between quantum wells. Consequently, the charge carriers are distributed homogeneously over the individual quantum wells. The tunnel transition zones also ensure that fewer non-radiating recombinations occur between electrons and holes in the active zones.

For example, the following layer sequence can arise in the direction of growth in the tunnel transition zone:
p-type layers, e.g. a p-cladding layer
highly doped p-layer, preferably comprising a ternary compound, InGaN in particular
diffusion barrier, as thin as possible, preferably quaternary, e.g. AlInGaN
highly doped n-layer, preferably comprising a ternary compound, InGaN in particular
n-type layers, e.g. an n-cladding layer

This is followed by at least one active zone.

The above-cited thin diffusion barrier is intended to separate the doping atoms of the respective layers.

The highly doped p-type layers and/or highly doped n-type layers can be configured as a superlattice. The energy gap in the region of the diffusion barrier is less than in the region of the p-type and n-type layers. In particular, the energy gap is preferably less than that of the highly doped p-type and n-type layers.

The gap between the regions of high charge carrier densities (electrons and holes) is small: the tunnel transition zone has a particularly small electrical resistance. A high charge carrier density and high tunnel probability can be achieved at the same time. The current expansion is therefore improved. This results in a good lateral current distribution and current coupling (=coupling in of charge carriers) in the sequence of semiconductor layers. The efficiency of the component is therefore increased and local warming due to excessive current flow in the sequence of semiconductor layers is avoided.

In a preferred embodiment, deep imperfections (midgap states) can be produced in the intermediate layer (can consist of a uniform substance or from: n-barrier and middle layer and p-barrier). The deep imperfections in the tunnel transition zone can be caused by foreign atoms.

In contrast with the usual dopants (Si, Mg), such foreign atoms have the advantage of generating electronic states that, in terms of energy, are disposed at approximately the center of the energy gap of the intermediate layer.

These imperfections make it easier for the charge carriers to tunnel through the intermediate layer. As a result, the efficiency of the tunnel transition zone is improved relative to a tunnel transition zone without intentionally inserted imperfections.

In the case of semiconductor bodies without a tunnel transition zone, the charge carriers must overcome high potential barriers in terms of energy at the transition from the n-conductive inclusion layer into the active zone or from the p-doped inclusion layer into the active zone. In the case of semiconductor bodies with a tunnel transition zone, such potential barriers rarely if ever occur.

The risk of a non-radiating recombination of charge carriers is reduced, thereby increasing the efficiency, particularly in the case of high operating currents, in other words in the case of high charge carrier concentrations.

In the case of semiconductor bodies having a multiple quantum well structure and tunnel transition zone, a plurality of active layers contribute to the radiation emission.

The tunnel transition zone allows the two opposing contacts of the semiconductor chip to be made from an n-conductive semiconductor material. This makes it possible to avoid the problem of the low p-conductivity of nitride compound semiconductors.

In a preferred embodiment of the laser diode assembly, the laser diodes are stacked vertically relative to the semiconductor substrate. By virtue of a monolithic growth process, it is possible to achieve a vertical gap between the laser diodes of less than approximately 20 μm. The vertical gap is preferably less than approximately 5 μm and particularly preferably less than approximately 1 μm.

As a result of using translucent tunnel diodes, vertical gaps between laser diodes can be achieved that are smaller than the wavelength of the light emitted by the laser diodes. In order to achieve this, the tunnel diodes have thicknesses of less than 50 nm, preferably between 30 nm and 5 nm. Vertical gaps between laser diodes of less than 100 nm can be achieved. In other words, the vertical gap of the laser diodes is significantly smaller than the wavelength of visible light (380 nm to 780 nm). The wave fields of the radiation from two laser diodes that are separated by a tunnel layer can penetrate into the tunnel layer. The radiation of a plurality of active zones can therefore be coupled. In order to avoid absorption losses in the tunnel layer, the thickness of the tunnel layer must be as small as possible and the material of the tunnel layer must absorb as little as possible of the electromagnetic radiation emitted by the laser diodes. Since the light typically passes 2 to 10 times through a laser resonator, the light passes through a section of up to 20 mm if a maximal length of the laser resonator is approximately 2 mm. Therefore a usable output signal can only be achieved if the absorption losses in the tunnel layer are minimal and preferably disappear completely.

With regard to quality, a translucent tunnel layer means that less laser radiation is absorbed in the tunnel layer than is generated in the active zones by means of induced emission. The absorption is proportional to

exp(−αd),

where α is the absorption coefficient of a medium and d is the optical path length that is covered by the laser radiation in the medium. The absorption coefficient α is negative in the active zones that amplify the laser light. In other words, it represents an amplification factor. The amplification factor is also referred to as a g0 factor. The absorption coefficient αT is positive in the tunnel layers that absorb the laser light. In this case, different active zones i can have different negative absorption coefficients αi. The amplification factor g0 corresponds to the value of ai. The active zones i are stacked monolithically. In order to achieve a translucent tunnel layer, the value of the smallest amplification factor αimin from all active zones i must be greater than the value of the absorption coefficient of the tunnel layers αT. The translucence of the tunnel layer can be defined as follows:

|αimin|>|αT|.

Preferably:

|αimin|>10×|αT|.

More preferably:

|αimin|>100×|αT|.

By way of example, some numerical values are specified for the amplification factor g0 in InGaN lasers. The amplification factor g0 is heavily dependent on the wavelength of the laser light. For a wavelength of over 500 nm, g0 is approximately 300/cm. In the case of shorter wavelengths, g0 can also be more than 1000/cm.

In order to achieve a translucent tunnel layer in accordance with the conditions specified above, the energy hole of the tunnel layer must be selected in such a way that it is larger than the energy of the radiation emitted by the laser diodes. In the case of InGaN compound semiconductors, the energy can be adjusted via the indium content. The greater the indium content, the smaller the energy hole (band edge energy). For example, in the case of an indium content of 22% and a gallium content of 78% in the active zone, the laser diodes emit in the blue spectral range at approximately 466 nm. In order to ensure that the blue light which circulates in the laser resonator is not absorbed in the tunnel diode, the indium content in the InGaN material of the tunnel diode must be less than 22%. In addition to InGaN, suitable materials for the translucent tunnel diode include the following ternary or quaternary material systems having a hexagonal crystal structure: AlGaN, AlInN, AlInGaN ((Al, Ga, In)N). Boron nitride compounds ((Al,Ga,In,B)N) are also suitable for tunnel layers, though the boron content here must be selected such that the crystalline integrity of the tunnel diode is preserved. The energy hole of the cited material systems can also be adjusted by using aluminum. The higher the aluminum content, the larger the energy hole. In a particularly advantageous embodiment, a maximal indium content is selected in order to give as many free charge carriers as possible. An increase in the indium content produces an increase in the quantity of dopant that can be incorporated in the crystal layer. Suitable dopants include magnesium and silicon, for example. The number of available charge carriers increases with the quantity of dopant. However, this only applies if the dopant is included at a lattice position. Reducing the energy gap (e.g. by increasing the indium concentration) also causes a reduction of the bonding energy of the dopants. The number of free charge carriers therefore increases again. As a result of a high indium content, however, the energy hole in the tunnel diode would be so small that laser radiation would be absorbed in the tunnel diode. By virtue of using aluminum, for example, the energy hole can be enlarged to such an extent that absorption no longer occurs.

As an alternative to adjusting the charge carrier concentration and the size of the energy hole by means of a suitable selection of the indium or aluminum concentration in the material of the tunnel layer, it is possible to use multiple layers, in particular so-called superlattices. For example, InN and GaN layers can be used. The layers are so thin, preferably less than 3 nm, that an electronic coupling occurs between the layers. As a result of this, individual layers can have a higher indium content and therefore more free charge carriers, without absorption losses occurring in the tunnel layer. In the above example, individual layers should have an indium content of more than 22% if the total indium content averaged over the whole tunnel layer is less than 22%.

In a preferred embodiment, the laser diodes are arranged horizontally, i.e. parallel with the semiconductor substrate.

By virtue of a monolithic growth process, it is possible to ensure that the horizontal gap between the laser diodes is less than approximately 100 μm. The horizontal gap is preferably less than approximately 20 μm, and particularly preferably less then 5 μm.

The small gaps in the monolithically grown laser diodes, said gaps being of the magnitude of the emission wavelength of the electromagnetic radiation, are particularly advantageous since they allow the light from various laser diodes to be emitted in a temporally and spatially coherent manner. The individual laser diodes are placed so closely next to each other that the wave fields overlap. This is possible if the gap between the laser diodes is less than approximately 15 μm. Phase coupling of the individual emissions occurs in this case, such that coherent radiation similar to that of a single laser is transmitted. This results in a greater degree of freedom and further possibilities in respect of the interaction between the light waves that are emitted by the individual laser diodes of the two-dimensional structure. Interaction relates to mode formation, mode amplification and mode suppression.

The present monolithic two-dimensional laser diode structure has advantageous properties, namely the extremely high optical power density at the same time as a reduced facet load and the geometric properties of the emission surface in the form of a two-dimensional expansion. This allows the use of less complicated optical imaging systems, i.e. a simple lens or lens system, for example. It also results in better imaging properties. The emission is effected from a largely centrically emitting laser light source having an aspect ratio close to 1. This has advantages in terms of the imaging behavior. It is particularly advantageous that the present invention can be used to generate extreme luminances.

The low manufacturing costs (epitaxy, processing and packaging) of the monolithically integrated two-dimensional laser diode assemblies are also advantageous in comparison with the construction of conventional laser arrays having emission of equal strength.

In a preferred development of the invention, the layer which faces towards the semiconductor substrate and adjoins the active zone is an n-waveguide, and the layer that faces away from the semiconductor substrate and adjoins the active zone is a p-waveguide. In other words, on top of the substrate in the direction of growth are disposed an n-layer, followed by an active zone, followed by a p-layer. This sequence is also referred to as conventional polarity. The deposition of the layer sequence can be repeated many times. Use of this epitaxial structure advantageously allows particularly small gaps to be realized between the laser diodes. Monolithically grown components having a layer sequence as described above can be operated at high voltages but low drive current. The undesired quantum-confined Stark effect nonetheless occurs, and distorts the course of the conduction band and valence band. This results in a poor overlap of the wave functions of the charge carriers in the laser-active zones. Therefore non-radiating recombination is highly probable.

In an advantageous embodiment, the layer which faces towards the semiconductor substrate and adjoins the active zone is a p-waveguide, and the layer that faces away from the semiconductor substrate and adjoins the active zone is an n-waveguide. In other words, on top of the substrate in the direction of growth are disposed a p-layer, followed by an active zone, followed by an n-layer. This is also referred to as inverted polarity or polarity-inverted laser diode (PILD) in this context. The laser diode assembly having the layer sequence described above can be operated at high voltages and low drive current. The internal piezoelectric field which occurs in the case of inverted polarity, and in particular in crystals having a polar structure (e.g. a Wurzit structure) such as GaN, compensates at least partially for other fields, also for external fields in particular. The injection of charge carriers into the active zone is improved thereby; more charge carriers can be captured in the active zone. The internal quantum efficiency is only slightly dependent on the current density. Furthermore, the unwanted lateral current expansion is clearly reduced by the transverse conductivity of the p-layers, which is lower than that of the n-layers. The electrical losses are reduced. The lower transverse conductivity of the p-layers is explained as follows: The p-layer has high resistance in comparison with n-layers. The p-layer is doped using Mg atoms (acceptors) and the n-layer is doped using Si atoms (donators). Doping with Mg atoms at 10²⁰ cm⁻³ results in a hole concentration of only ˜10¹⁸ cm⁻³. The Mg atoms and the Si atoms are activated by means of thermal excitation or by an electron beam or by means of microwave excitation. The Mg acceptors have a very high bonding energy of 165 meV. The Si donators are bonded by an energy of just 50 meV.

The lateral current expansion results in an undefined widening of the injected current, said widening being dependent on the current and power. This results in an uncontrolled widening of the light spots and hence a reduced luminance. The operating current must be increased, since otherwise no population inversion will be achieved at the edge of the undefined, current-widened region.

The monolithically stacked laser diodes result in laser bars of modest structural height. This allows better activation of the p-layers. The activation using magnesium in the semiconductor systems AlN, InN and GaN and other broadband semiconductors is heavily dependent on the level of hydrogen that has been driven out. The hydrogen can hardly diffuse through n-layers. The connection of stacked laser diodes and laser bars of modest structural height makes it possible to drive out the hydrogen sideways. The activation level of the p-layers is drastically increased thereby. This results in a reduction of the ohmic losses in the vertically stacked laser diodes and hence in improved operating conditions. In other words, the activation of covered p-layers is achieved by removing the hydrogen by means of lateral diffusion and evaporation through side surfaces of the laser bars. In particular, the hydrogen does not have to be removed via the upper n-type top layer.

In a preferred development of the invention, the laser diode assembly features laser ridges, which are used to guide the laser radiation. In this case, the active region is laterally limited to a strip by refractive index jumps. This is known as index guiding. The optical wave is guided in a waveguide and can only excite the induced emission in said waveguide. The formation of the waveguide can be effected by means of different layer thicknesses and/or layer sequences. Various effective refractive indices are produced inside and outside the strip in this case. Claddings and waveguides form a quasi step-index fiber. In order to improve the electrical confinement, the contact is also designed as a strip. In a development of the method, provision is made for laser ridges that direct the laser radiation in a particularly effective manner by means of an index guide. The limited lateral diffusion of the charge carriers and the resulting low threshold current are advantageous.

Dissemination of laser light can also be gain-guided. In this case, the active zone is laterally delimited by the injection of charge carriers onto a strip (e.g. oxide strip laser). The contact is introduced onto the p-conductive semiconductor material through a window in an insulating oxide. In an unbroken active layer, an amplification profile occurs laterally that is proportional to the current density and is associated with a lowering of the refractive index. In the region of greatest amplification, i.e. highest stimulated emission, the refractive index is raised slightly as a result of reduced charge carrier concentration, such that the optical wave is concentrated by this current-induced waveguide onto the area of greatest amplification. This is also called active wave guiding. In other words, the spatial delimitation of the current path is effected by means of oxide windows. Particular advantages of gain-guided lasers are their ease of manufacture, high optical powers and stimulation of many modes.

The advantage of index-guided laser diodes in comparison with gain-guided laser diodes is the generally lower threshold current.

The width of the laser ridges can be used to control whether a transverse mode is started (ridge widths of less than approximately 2 μm) or multimode operation applies.

In a preferred development of the invention, the laser diode assembly has laser diodes that emit electromagnetic radiation in wavelength ranges that are at least partially different from each other. By means of varying an indium concentration in the active zones, at least one first laser diode can emit electromagnetic radiation in the blue to UV spectral range and at least one second laser diode can emit electromagnetic radiation in the green to yellow spectral range.

In a preferred development of the invention, at least one first laser diode can emit electromagnetic radiation in the blue to UV spectral range, at least one second laser diode can emit electromagnetic radiation in the green to yellow spectral range, and at least one third laser diode can emit electromagnetic radiation in the red spectral range.

The active zone having the least indium content is deposited first on the substrate. The active zone having the greatest indium content is deposited last.

In the embodiment comprising red, green and blue laser diodes, the following sequence is used for the deposition: The active zone from which the blue laser diode is produced is deposited onto the substrate first. Then the active zone from which the green laser diode is produced is deposited. Finally, the active zone from which the red laser diode is produced is deposited.

It is also advantageously possible for a plurality of active zones having indium content to be stacked monolithically one above the other. For example, one active zone for emission of blue light, two active zones for the emission of green light and one active zone for the emission of red light.

Laser diodes based on the material system InGaAlN are examined below. According to the invention, laser diodes that emit in the UV range have an indium concentration of between approximately 5% and approximately 10% in the active zone. For emission in the blue range, the indium concentration in the active zone must be between approximately 15% and approximately 25%. In the green range, the indium concentration in the active zone is between approximately 25% and approximately 35%. In the yellow range, the indium concentration in the active zone is between approximately 35% and approximately 45%. In the red range, the indium concentration in the active zone is greater than approximately 45%, and preferably between 45% and 60%. This monolithic integration of laser diodes, which cover the complete visible spectrum when combined together, is particularly advantageous for applications in which laser radiation having various wavelengths is required in the smallest possible space.

The invention claims a method for manufacturing a laser diode assembly, comprising the steps:
providing a semiconductor substrate,
epitaxially depositing a sequence of semiconductor layers, thereby
   forming at least two laser stacks, each having an active zone, and
   forming at least one ohmic contact, wherein the laser stacks and the ohmic contact are monolithically deposited on the semiconductor substrate, wherein
      the laser stacks are connected together in an electrically conductive manner by the ohmic contact, and wherein laser diodes formed from the laser stacks form a two-dimensional structure.

### BRIEF DESCRIPTION OF THE DRAWINGS

Various exemplary embodiments of the inventive solution are explained in greater detail below with reference to the drawings, in which:

FIG. 1 shows a first epitaxial structure;

FIG. 2 shows a second epitaxial structure;

FIG. 3 shows a third epitaxial structure;

FIG. 4 shows a fourth epitaxial structure;

FIG. 5 shows a first chip structure based on the first epitaxial structure from FIG. 1;

FIG. 6 shows a second chip structure based on the first epitaxial structure from FIG. 1;

FIG. 7a shows a third chip structure based on the first epitaxial structure from FIG. 1;

FIG. 7b shows the third chip structure from FIG. 7a in a three-dimensional view based on the first epitaxial structure from FIG. 1;

FIG. 8 shows a fourth chip structure based on the first epitaxial structure from FIG. 1;

FIG. 9 shows a fifth chip structure;

FIG. 10a schematically shows the emission line of a single laser diode;

FIG. 10b schematically shows a plurality of emission lines with a rectangular envelope; and

FIG. 10c schematically shows a plurality of emission lines with an envelope of Gaussian curvature.

### EXEMPLARY EMBODIMENTS OF THE OPTOELECTRONIC COMPONENT

Elements that are identical, of the same type or have identical functionality are denoted by the same reference signs in the figures. The figures and the size ratios of the elements illustrated in the figures are not to scale. The size of individual elements may instead be exaggerated to aid clarity and understanding.

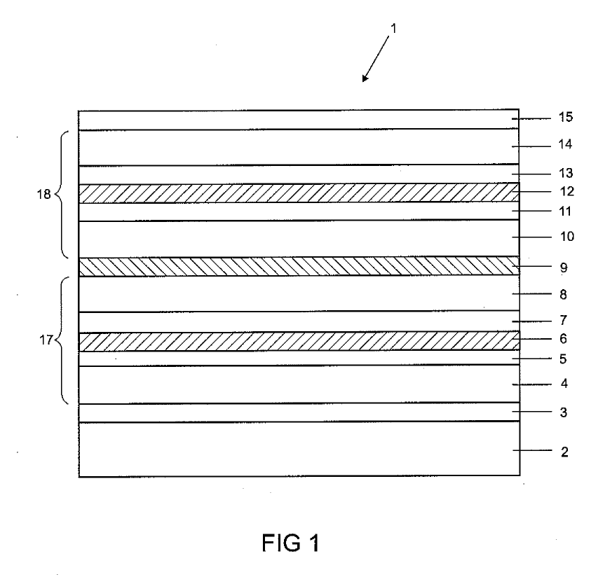

FIG. 1 shows an epitaxial structure in which the tunnel diode 9 is arranged outside of the cladding layer. It shows a layer sequence which has conventional polarity. Conventional polarity means that the p-layers 7, 8; 13, 14 follow in each case on those sides of the two active zones 6, 12 which face away from the semiconductor substrate 2. In other words, the p-layers 7, 8; 13, 14 are deposited after the active zone 6, 12. The n-doped semiconductor substrate 2 is followed in the direction of growth by a buffer layer 3, a first n-cladding layer 4, a first n-waveguide 5, a first active zone 6, a first p-waveguide 7, a first p-cladding layer 8, a tunnel diode 9, a second n-cladding layer 10, a second n-waveguide 11, a second active zone 12, a second p-waveguide 13, a second p-cladding layer 14 and a p-contact layer 15.

A first laser stack 17 comprises the first n-cladding layer 4, the first n-waveguide 5, the first active zone 6, the first p-waveguide 7 and the first p-cladding layer. A second laser stack 18 comprises the second n-cladding layer 10, the second n-waveguide 11, the second active zone 12, the second p-waveguide 13 and the second p-cladding layer.

Conventional polarity means that, in respect of the laser diodes which are formed from the laser stacks 17 and 18, the A-sides adjoin the top sides, i.e. the sides facing away from the semiconductor substrate, of the active zones 6 and 12.

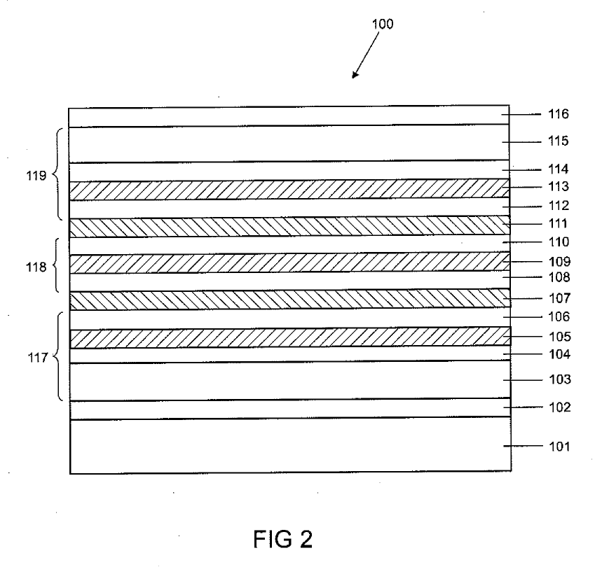

FIG. 2 shows an epitaxial structure in which, unlike FIG. 1, the tunnel diodes 107 and 111 are arranged inside the cladding layers. It shows a layer sequence having conventional polarity as per FIG. 1 above. With regard to the laser diodes that are formed from the laser stacks 117, 118 and 119, the p-sides adjoined the top sides of the active zones 105, 109 and 113. The n-doped substrate 101 is followed in the direction of growth by a buffer layer 102, an n-cladding layer 103, a first n-waveguide 104, a first active zone 105, a first p-waveguide 106, a first tunnel diode 107, a second n-waveguide 108, a second active zone 109, a second p-waveguide 110, a second tunnel diode 111, a third n-waveguide 112, a third active zone 113, a third p-waveguide 114, a p-cladding layer 115 and a p-contact layer 116.

A first laser stack 117 comprises the n-cladding layer 103, the first n-waveguide 104, the first active zone 105 and the first p-waveguide 106. A second laser stack 118 comprises the second n-waveguide 108, the second active zone 109 and the second p-waveguide 110. A third laser stack 119 comprises the third n-waveguide 112, the third active zone 113, the third p-waveguide 114 and the p-cladding layer 115.

As a result of the tunnel diodes being arranged inside the cladding layers in FIG. 2, the active zones are closer together. This allows a smaller structural height of the laser diode assembly.

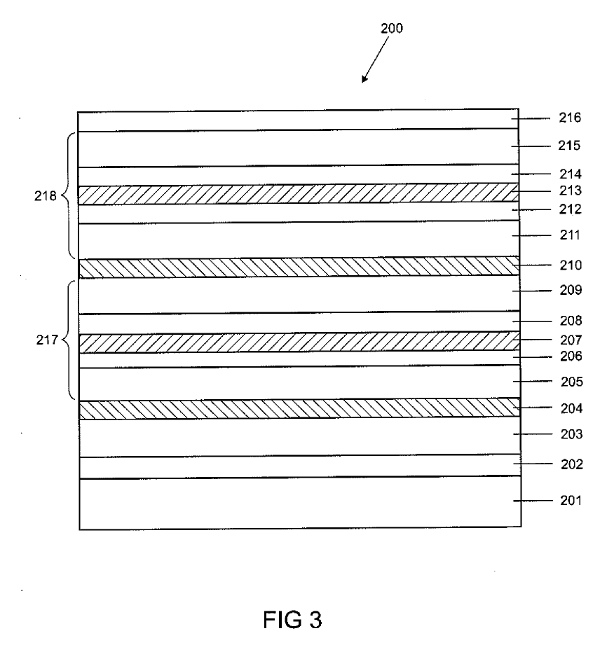

FIG. 3 shows an epitaxial structure in which the tunnel diodes 204 and 210 are arranged outside the cladding layers. It shows a layer sequence which has inverted polarity. The layer which faces towards the semiconductor substrate 201 and adjoins the active zone 207, 213 is a p-waveguide 206, 212. The layer which faces way from the semiconductor substrate 201 and adjoins the active zone 207, 213 is an n-waveguide 208, 214. The layer sequence comprises a first laser stack 217 and a second laser stack 218. The semiconductor substrate 201 is followed in the direction of growth by a buffer layer 202, a first n-cladding layer 203, a first tunnel diode 204, a first p-cladding layer 205, a first p-waveguide 206, a first active zone 207, a first n-waveguide 208, a second n-cladding layer 209, a second tunnel diode 210, a second p-cladding layer 211, a second p-waveguide 212, a second active zone 213, a second n-waveguide 214, a third n-cladding layer 215 and then an n-type contact layer 216.

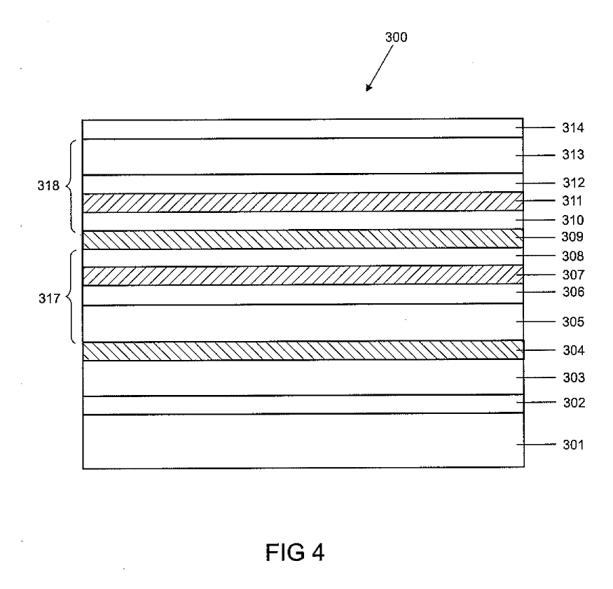

FIG. 4 shows an epitaxial structure in which the first tunnel diode 304 is arranged outside the cladding layers and the second tunnel diode 309 is arranged inside the cladding layers. It shows a layer sequence having inverted polarity as per FIG. 3 above. The first tunnel diode 304 is essential since the substrate is n-conductive. The layer which faces towards the semiconductor substrate 301 and adjoins the active zone 307, 311 is a p-waveguide 306, 310. The layer which faces away from the semiconductor substrate 301 and adjoins the active zone 307, 311 is an n-waveguide 308, 312.

The semiconductor substrate 301 is followed in the direction of growth by a buffer layer 302, a first n-cladding layer 303, a first tunnel diode 304, a p-cladding layer 305, a first p-waveguide 306, a first active zone 307, a first n-waveguide 308, a second tunnel diode 309, a second p-waveguide 310, a second active zone 311, a second n-waveguide 312, a second n-cladding layer 313 and an n-type contact layer 314.

The first tunnel diode 304 is required if the semiconductor substrate 301 is of the n-type.

The layer sequence comprises a first laser stack 317 and a second laser stack 318.

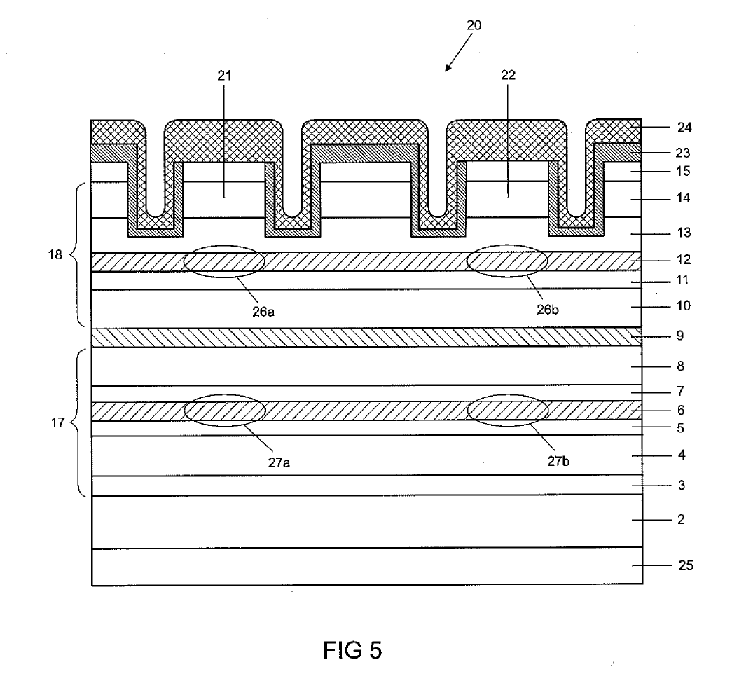

FIGS. 5 to 8 are based on the epitaxially deposited layer sequehce illustrated in FIG. 1, i.e. comprising two active zones 6 and 12 and a tunnel diode 9 which are arranged outside the cladding layers 8, 10.

FIG. 5 shows a first exemplary embodiment of a chip structure 20 in a two-dimensional representation. The laser diode assembly 20 comprises a semiconductor substrate 2, two laser stacks 17 and 18, each of which has an active zone 6 and 12, and an ohmic contact 9. The laser stacks 17 and 18 and the ohmic contact 9 are monolithically deposited onto the semiconductor substrate 2. The laser stacks 17 and 18 are electrically connected by the ohmic contact 9. Laser diodes 26a, 26b, 27a and 27b that are formed from the laser stacks 17 and 18 form a two-dimensional structure. The laser diodes 26a, 26b, 27a and 27b are stacked vertically relative to the semiconductor substrate 2. The vertical gap between the laser diodes 26a, 26b, 27a and 27b is less than approximately 20 μm, preferably less than approximately 5 μm, and particularly preferably less than approximately 1 μm. The vertical gap between the laser diodes 26a, 26b, 27a and 27b is preferably smaller than the wavelength of the light that is emitted by the laser diodes. The ohmic contact 9 is designed as a tunnel diode and is translucent.

In addition, the laser diodes 26a, 26b, 27a and 27b are so arranged as to be horizontal (i.e. parallel) relative to the semiconductor substrate 2. The horizontal gap between the laser diodes 26a, 26b, 27a and 27b is less than approximately 100 μm, preferably less than approximately 20 μm, and particularly preferably less than approximately 5 μm.

An n-contact metallization 25 is applied onto the bare side of the semiconductor substrate.

The layer sequence comprising p-contact layer 15, second p-cladding layer 14 and second p-waveguide 13 are structured by means of etching or lithography, for example. The structuring stops just before the second active zone, in order to achieve at least partial index guidance of the laser light. A passivization 23 is deposited onto at least sections of these layers. The passivization 23 is open for contacting above the laser ridges 21 and 22. A p-contact metallization 24 is formed by deposition over the whole surface. A first laser ridge 21 and a second laser ridge 22 are formed. Two laser diodes 26a and 26b are formed in the second active zone 12 and guide the laser light by means of an index guide. The second active zone 12 is laterally limited to a strip by means of a refractive index jump. The refractive index jump is generated by the transition zone comprising second active zone 12, second p-waveguide 13 and passivization 23. A double heterostructure is constructed in a lateral direction, such that the active strip is surrounded on all sides by material having a smaller refractive index. The optical wave is guided in a waveguide and can only excite the induced emission therein. The contact is designed as a strip in order to improve the electrical confinement.

Two gain-guided laser diodes 27a and 27b are formed in the first active zone 6, while the active zone 6 is laterally delimited by the injection of charge carriers. An amplification profile which is proportional to the current density and is associated with a lowering of the refractive index occurs laterally in the unbroken active zone 6. In the region of greatest amplification, i.e. highest stimulated emission, the refractive index is raised slightly as a result of reduced charge carrier concentration, such that the optical wave is concentrated by this current-induced waveguide onto the area of greatest amplification. Advantages of gain-guided laser diodes include ease of manufacture and high optical powers. Disadvantages include the high threshold currents resulting from the lateral diffusion of the charge carriers.

The associated light spots of the laser diodes can also be also found at the positions where the laser diodes 26a, 26b, 27a and 27b are marked. This applies likewise to all of the following figures.

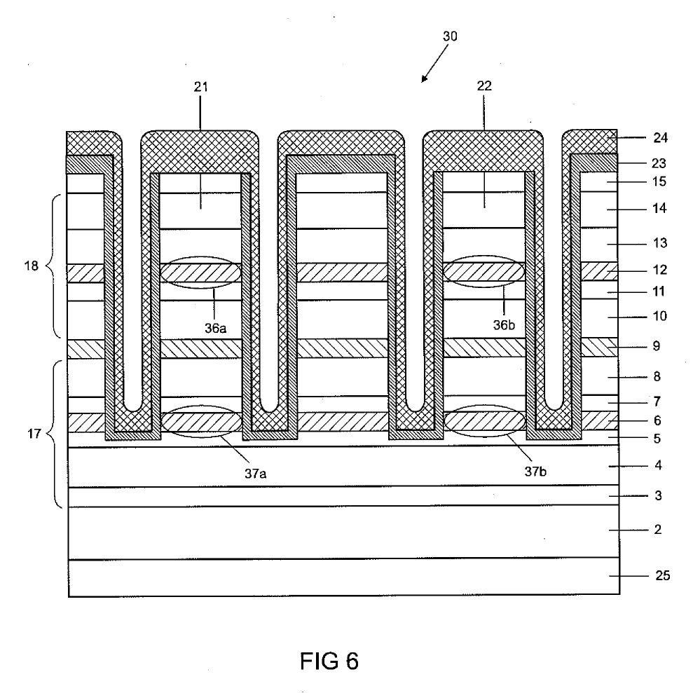

FIG. 6 shows a second exemplary embodiment of a chip structure 30 in a two-dimensional representation. As in the case of FIG. 5 above, the chip structure 30 has two laser ridges 21, 22. In contrast with FIG. 5, FIG. 6 shows a chip structure in which the laser ridges 21 and 22 extend from the p-contact metallization 24 to the first n-waveguide 5. Therefore the laser ridges 21 and 22 cut through the second active zone 12, the tunnel diode 9 and the first active zone 6 in particular. The trenches thus formed result in part-layers that are isolated from each other. The chip structure 30 has a first index-guided laser diode 36a, a second index-guided laser diode 36b, a third index-guided laser diode 37a and a fourth index-guided laser diode 37b.

The chip structure 30 allows an improved activation of the p-doped layers as a function of the level of hydrogen that has been driven out. The p-conductivity increases. The activation step assists the outward diffusion from the p-doped regions of undesired elements, in particular hydrogen, that are contained with the dopant (magnesium) in the semiconductor material. It is therefore possible to manufacture chip structures 30 that have a lower forward voltage.

By virtue of the deep etching of the chip structure 30, hydrogen can be driven out sideways in a particularly effective manner.

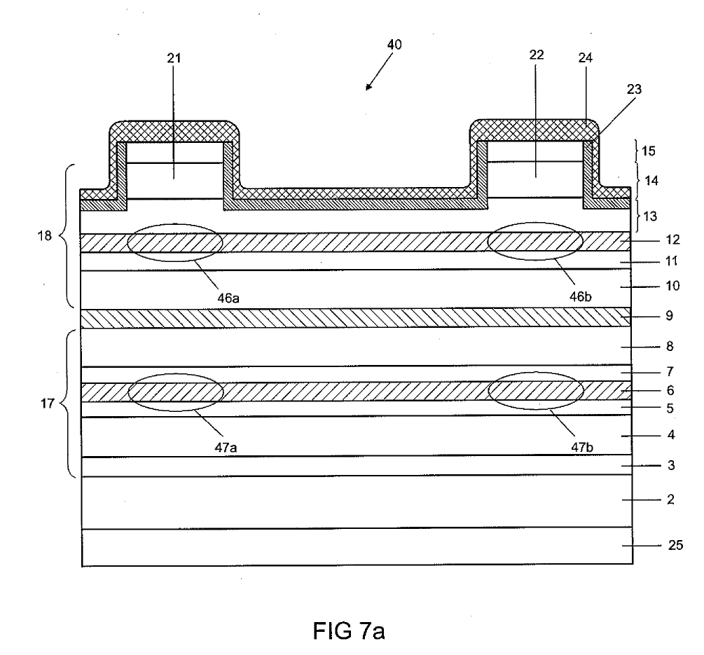

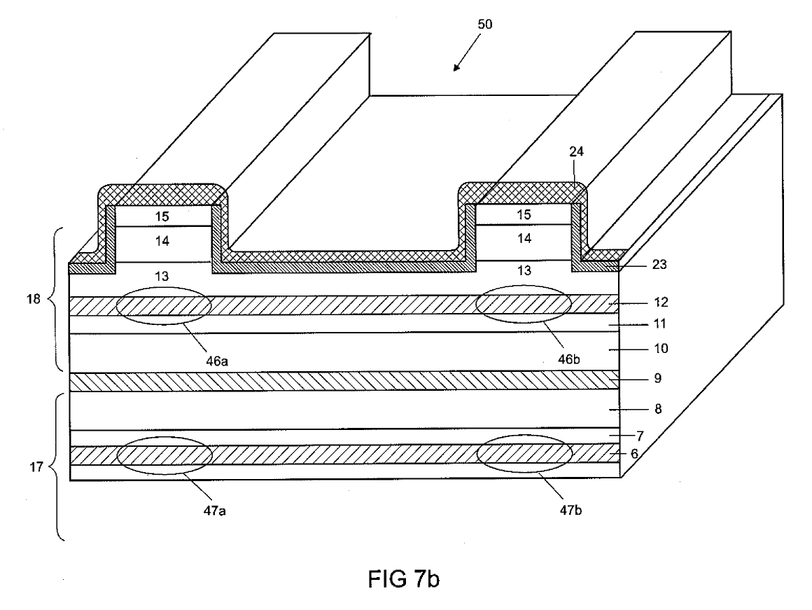

FIG. 7a shows a third exemplary embodiment of a chip structure 40 in a two-dimensional representation. In contrast with FIGS. 5 and 6, the FIG. 7a features a chip structure 40 in which the refractive index jump is moved further out towards the laser ridges 21, 22 than is the case in FIG. 5 and FIG. 6. The chip structure has a first index-guided laser diode 46a and a second index-guided laser diode 46b. FIG. 7a additionally features a first gain-guided laser diode 47a and a second gain-guided laser diode 47b.

FIG. 7b shows the exemplary embodiment of a chip structure as per FIG. 7a in a three-dimensional representation. As already shown in FIG. 7a, the chip structure 40 features a first index-guided laser diode 46a and a second index-guided laser diode 46b. Also provided are first gain-guided laser diode 47a and a second gain-guided laser diode 47b.

The laser diodes 46a, 46b, 47a and 47b and the associated light spots of the laser diodes are not illustrated as discrete entities. More specifically, the laser diodes 46a, 46b, 47a and 47b extend in three-dimensions, while the light spots only extend in two-dimensions.

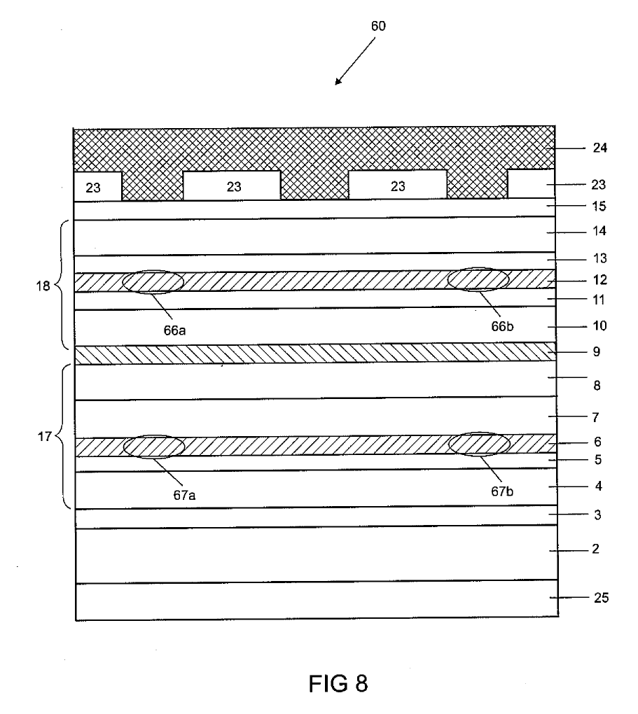

FIG. 8 shows an exemplary embodiment of a chip structure 60 in a two-dimensional representation. The chip structure 60 features exclusively gain-guided laser diodes 66a, 66b, 67a and 67b. There is no refractive index jump. Such an arrangement is also known as an oxide strip laser. This arrangement is simple to manufacture and is suitable for high output powers.

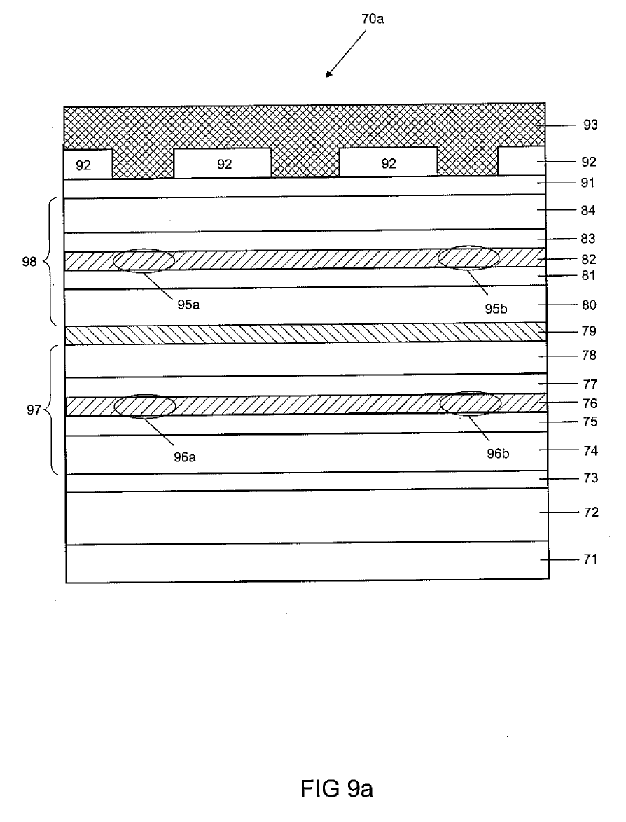

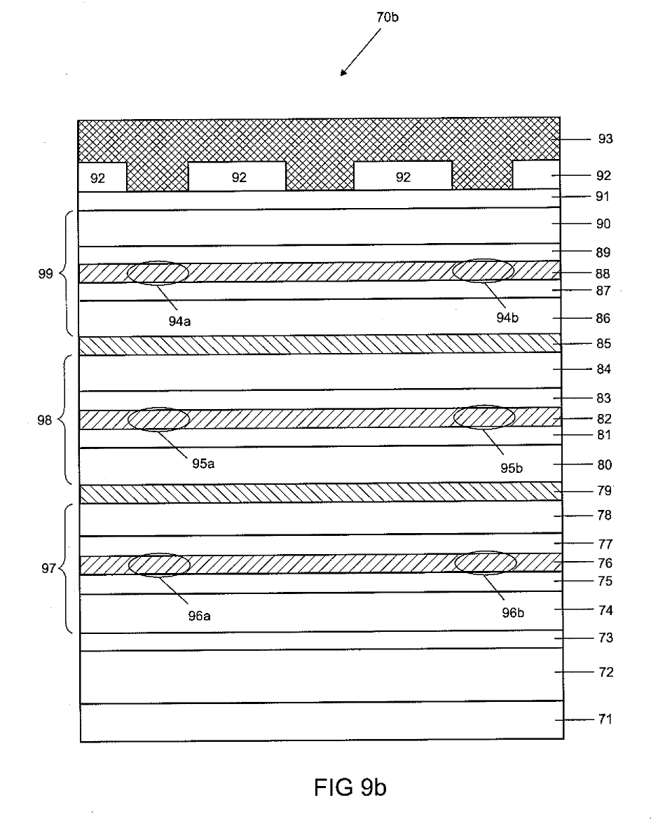

FIG. 9a shows a fifth exemplary embodiment of a chip structure 70a in a two-dimensional representation. The chip structure 70a features exclusively gain-guided laser diodes. This arrangement is simple to manufacture and is suitable for high output powers. The chip structure represents a monolithically grown light source, which simultaneously emits light in the green or yellow spectral range and in the blue spectral range. The laser diodes 95a and 95b emit in the green or yellow spectral range and the laser diodes 96a and 96b emit in the blue spectral range.

The layer sequence of the sixth exemplary embodiment is as follows: The starting layer is the semiconductor substrate 72. Applied to the underside of said starting layer is the n-contact metallization 71. The buffer layer 73 is deposited onto the top side of the semiconductor substrate 72. This is followed in the direction of growth by a first n-cladding layer 74, a first n-waveguide 75, a first active zone 76 with emission of blue light, a first p-waveguide 77, a first p-cladding layer 78, a first tunnel diode 79, a second n-cladding layer 80, a second n-waveguide 81, a second active zone 82 with emission of green or yellow light, a second p-waveguide 83, a second p-cladding layer 84, a highly doped p-contact layer 91, a passivization 92 and finally a p-contact metallization 93.

In the present exemplary embodiment, which is based on the single material system InGaAlN, the stack sequence of the active zones starting from the semiconductor substrate is as follows:
blue 76
green or yellow 82.
   A white light source can be generated by combining blue and yellow laser light.

Alternatively, any other wavelength can be generated by the emission of various laser wavelengths.

FIG. 9b shows a sixth exemplary embodiment of a chip structure 70b in a two-dimensional representation. The chip structure 70b features exclusively gain-guided laser diodes. This arrangement is simple to manufacture and is suitable for high output powers. The chip structure represents a monolithically grown light source, which simultaneously emits light in the red, green and blue spectral range. The laser diodes 94a and 94b emit in the red spectral range, the laser diodes 95a and 95b emit in the green spectral range, and the laser diodes 96a and 96b emit in the blue spectral range.

The arrangement can be based on a single InGaAlN material system for the simultaneous emission of laser light in all three primary colors. Alternatively the arrangement can be based on the material system (Al,In)GaN for the simultaneous emission of green and blue laser light, and on the material system InGaAlP for the emission of red laser light.

The layer sequence of the sixth exemplary embodiment is as follows: The starting layer is the semiconductor substrate 72. Applied to the underside of said starting layer is the n-contact metallization 71. The buffer layer 73 is deposited onto the top side of the semiconductor substrate 72. This is followed in the direction of growth by a first n-cladding layer 74, a first n-waveguide 75, a first active zone 76 with emission of blue light, a first p-waveguide 77, a first p-cladding layer 78, a first tunnel diode 79, a second n-cladding layer 80, a second n-waveguide 81, a second active zone 82 with emission of green light, a second p-waveguide 83, a second p-cladding layer 84, a second tunnel diode 85, a third n-cladding layer 86, a third n-waveguide 87, a third active zone 88 with emission of red light, a third p-waveguide 89, a third p-cladding layer 90, a third, highly doped p-contact layer 91, a passivization 92 and finally a p-contact metallization 93.

In the present exemplary embodiment, based on the single material system InGaAlN, the stack sequence of the active zones starting from the semiconductor substrate is as follows:
blue 76
green 82
red 88.

This sequence is advantageous because the most indium-rich and hence most temperature-sensitive active zone red 88 is deposited last in this case. The combination of blue, green and red laser light can be combined to form a white light source that provides a light spot of extreme luminance. Laser diodes represent key components for the RGB laser projection, wherein the laser wavelengths are typically 600 to 660 nm for RED, 430 to 470 nm for BLUE and 510 to 550 nm for GREEN.

Laser-based RGB light sources have many advantages (highly efficient, long service life, depth of focus, compact structural format) over conventional projection systems (beamer lamps, LED-based projectors).

By virtue of the small emitting surface and the limited angle of emission, such a laser-based light source has a greater luminance than a conventional LED-based light sources by several orders of magnitude.

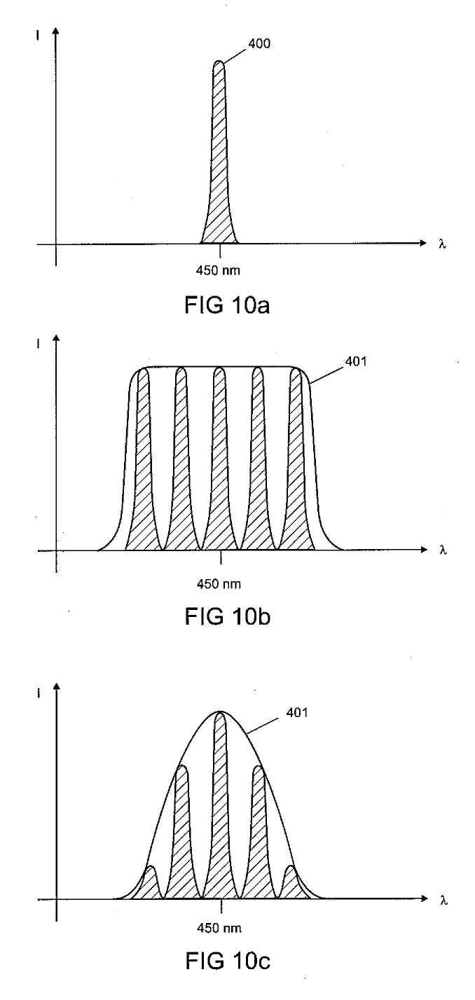

FIG. 10a shows laser light 400 coming from a laser diode. The laser diode has one active zone. Each active zone has one or more quantum wells. Two to five quantum wells are preferably used in each active zone. The quantum wells are separated from each other by barrier layers. The light that is emitted by the quantum wells of an active zone is highly monochromatic. As a result of the high coherency which derives from the narrow wavelength distribution of laser diodes, laser-based red-green-blue (RGB) light sources are prone to undesired interference phenomena in the projection images. These brightness fluctuations are evident as so-called “speckle patterns”. The undesired “speckling” limits the use of laser light sources for projection purposes. The speckle pattern is seen as a coarsely granulated pattern of the beam intensity. For example, the half-width for monochromatic blue light at 450 nm is approximately 0.5 to 1.5 nm. In order to reduce the speckle pattern, the emitted laser radiation must have a broader wavelength distribution than the typical values in the nm range or less. One means of reducing the speckling would be to broaden the wavelength distribution epitaxially by means of suitable inhomogeneities in the active zone (e.g. by using higher growth temperatures). However, these inhomogeneities also result in greater losses, reduced efficiency and hence a shorter service life.

FIG. 10b shows the emission of laser light which has a greater spectral width than in FIG. 10a. The laser light is composed of laser light from five different active zones, these being connected together via translucent tunnel layers. The indium content varies between the different active zones. The active zones selectively feature differences in their emission wavelength. Collectively, this results in a broader wavelength distribution of the emitted light. For example, two to 20 different active zones having suitable wavelength differences between 0.5 nm and 20 nm can be arranged one above the other. Concurrent operation then results in the desired width of wavelength distribution. For example, the emission lines from the various active zones overlap in such a way that an envelope 401 is generated with a spectral width of approximately 4 to 20 nm at an average wavelength of 450 nm. The use of translucent tunnel diodes is essential for this purpose. The laser light is speckle-free and is therefore highly suitable for laser projection. This method can be performed using any of these basic colors (RED-GREEN-BLUE) and therefore result in a speckle-free laser projection. The envelope 401 has a rectangular shape. The rectangular profile is produced because all of the active zones are equally efficient.

Like FIG. 10b, FIG. 10c shows a laser emission which has a greater spectral width than in FIG. 10a. The laser light is composed of laser light from five different active zones, these being connected together via translucent tunnel layers. Unlike

FIG. 10b, an envelope having approximately Gaussian curvature is produced for the intensity distribution as a function of the wavelength. The Gaussian curvature can be achieved as a result of the central active zone being more efficient than the outer active zones. The efficiency of the active zones can be adjusted by means of the growth temperature. If the growth temperature is lower than the optimal growth temperature, the resulting crystal quality is worse and the efficiency of the active zone is reduced. If the growth temperature is higher than the optimal growth temperature, the indium content lacks uniformity over the extent of the quantum wells. This again reduces the efficiency of the active zone.

The laser diode assembly and the method for manufacturing a laser diode assembly are described above with reference to a number of exemplary embodiments for the purpose of illustrating the fundamental idea. In this case, the exemplary embodiments are not limited to specific combinations of features. Even if certain features and configurations are only described in the context of a specific exemplary embodiment or individual exemplary embodiments, they can also be combined with other features from other exemplary embodiments in each case. It is likewise conceivable for individual features or particular configurations to be omitted or added in exemplary embodiments, provided the general technical teaching is still realized.

Even though the steps of the method for manufacturing a laser diode assembly are described in a specific sequence, each of the methods described in this disclosure can naturally be executed in any other preferable sequence, wherein method steps can also be omitted or added, provided there is no deviation from the fundamental idea of the technical teaching described herein.

### LIST OF REFERENCE SIGNS

1 First exemplary embodiment of a layer sequence
2 Substrate
3 Buffer layer
4 First n-cladding layer
5 First n-waveguide
6 First active zone
7 First p-waveguide
8 First p-cladding layer
9 Tunnel diode
10 Second n-cladding layer
11 Second n-waveguide
12 Second active zone
13 Second p-waveguide
14 Second p-cladding layer
15 p-contact layer
17 First laser stack
18 Second laser stack
20 First exemplary embodiment of a chip structure
21 First laser ridge
22 Second laser ridge
23 Passivization
24 p-contact metallization
25 n-contact metallization
26a First index-guided laser diode
26b Second index-guided laser diode
27a First gain-guided laser diode
27b Second gain-guided laser diode
30 Second exemplary embodiment of a chip structure
36a First index-guided laser diode
36b Second index-guided laser diode
37a Third index-guided laser diode
37b Fourth index-guided laser diode
40 Third exemplary embodiment of a chip structure
46a First index-guided laser diode
46b Second index-guided laser diode
47a First gain-guided laser diode
47b Second gain-guided laser diode
50 Section of a spatial representation of the third exemplary embodiment of a chip structure
60 Fourth exemplary embodiment of a chip structure
66a First gain-guided laser diode
66b Second gain-guided laser diode
67a Third gain-guided laser diode
67b Fourth gain-guided laser diode
70a Fifth exemplary embodiment of a chip structure
70b Sixth exemplary embodiment of a chip structure
71 n-contact metallization
72 Semiconductor substrate, n-type
73 Buffer layer
74 First n-cladding layer
75 First n-waveguide
76 First active zone with emission of blue light
77 First p-waveguide
78 First p-cladding layer
79 First tunnel diode
80 Second n-cladding layer
81 Second n-waveguide
82 Second active zone with emission of green light
83 Second p-waveguide
84 Second p-cladding layer
85 Second tunnel diode
86 Third n-cladding layer
87 Third n-waveguide
88 Third active zone with emission of red light
89 Third p-waveguide
90 Third p-cladding layer
91 p-contact layer
92 Passivization
93 p-contact metallization
94a First gain-guided laser diode
94b Second gain-guided laser diode
95a Third gain-guided laser diode
95b Fourth gain-guided laser diode
96a Fifth gain-guided laser diode
96b Sixth gain-guided laser diode
97 First laser stack
98 Second laser stack
99 Third laser stack
100 Second exemplary embodiment of a layer sequence
101 Substrate
102 Buffer layer
103 n-cladding layer
104 First n-waveguide
105 First active zone
106 First p-waveguide
107 First tunnel diode
108 Second n-waveguide
109 Second active zone
110 Second p-waveguide
111 Second tunnel diode
112 Third n-waveguide
113 Third active zone
114 Third p-waveguide
115 p-cladding layer
116 p-contact layer
117 First laser stack
118 Second laser stack

119 Third laser stack
200 Third exemplary embodiment of a layer sequence
201 Substrate
202 Buffer layer
203 First n-cladding layer
204 First tunnel diode
205 First p-cladding layer
206 First p-waveguide
207 First active zone
208 First n-waveguide
209 Second n-cladding layer
210 Second tunnel diode
211 Second p-cladding layer
212 Second p-waveguide
213 Second active zone
214 Second n-waveguide
215 Third n-cladding layer
216 n-type contact layer
217 First laser stack
218 Second laser stack
300 Fourth exemplary embodiment of a layer sequence
301 Substrate
302 Buffer layer
303 First n-cladding layer
304 First tunnel diode
305 p-cladding layer
306 First p-waveguide
307 First active zone
308 First n-waveguide
309 Second tunnel diode
310 Second p-waveguide
311 Second active zone
312 Second n-waveguide
313 Second n-cladding layer
314 n-type contact layer
317 First laser stack
318 Second laser stack
400 Individual emission
401 Envelope

1. A laser diode assembly comprising:
a semiconductor substrate;
at least two laser stacks, each having one active zone; and
at least one translucent ohmic contact, wherein the laser stacks and the translucent ohmic contact are monolithically deposited on the semiconductor substrate,
wherein the laser stacks are electrically connected by the translucent ohmic contact, and
wherein edge emitting laser diodes that are formed from the laser stacks form a two-dimensional structure.

2. The laser diode assembly as claimed in claim 1, wherein the translucent ohmic contact is a tunnel diode.

3. The laser diode assembly as claimed in claim 1, wherein the laser diodes are stacked vertically relative to the semiconductor substrate.

4. The laser diode assembly as claimed in claim 1, wherein the vertical gap between the laser diodes is less than approximately 20 μm.

5. The laser diode assembly as claimed in claim 1, wherein the vertical gap between the laser diodes is less than the wavelength of the light that is emitted by the laser diodes.

6. The laser diode assembly as claimed in claim 1, wherein the laser diodes are arranged in a horizontal direction, i.e. parallel with the semiconductor substrate.

7. The laser diode assembly as claimed in claim 6, wherein the horizontal gap between the laser diodes is less than approximately 100 μm.

8. The laser diode assembly as claimed in claim 1, wherein the layer that faces towards the semiconductor substrate and adjoins the active zone is a p-waveguide, and the layer that faces away from the semiconductor substrate and adjoins the active zone is an n-waveguide.

9. The laser diode assembly as claimed in claim 1, wherein the laser diodes are gain-guided.

10. The laser diode assembly as claimed in claim 1, wherein the laser diodes are index-guided.

11. The laser diode assembly as claimed in claim 10, wherein trenches between laser ridges that feature the index-guided laser diodes cut through all active zones.

12. The laser diode assembly as claimed in claim 1, wherein the active zones are configured such that the laser diodes from different active zones emit electromagnetic radiation in differing wavelength ranges.

13. The laser diode assembly as claimed in claim 12 from a GaN semiconductor system, wherein by varying an indium concentration in the active zones at least one first laser diode emits electromagnetic radiation in the blue to UV spectral range and at least one second laser diode emits electromagnetic radiation in the green to yellow spectral range.

14. The laser diode assembly as claimed in claim 12 from a GaN semiconductor system, wherein by varying an indium concentration in the active zones at least one first laser diode emits electromagnetic radiation in the blue to UV spectral range, at least one second laser diode emits electromagnetic radiation in the green to yellow spectral range and at least one third laser diode emits electromagnetic radiation in the red spectral range.

15. The laser diode assembly as claimed in claim 13, wherein
the indium concentrations are between approximately 5% and approximately 10% for laser diodes in the UV range,
the indium concentrations are between approximately 15% and approximately 25% for laser diodes in the blue range,
the indium concentrations are between approximately 25% and approximately 35% for laser diodes in the green range,
the indium concentrations are between approximately 35% and approximately 45% for laser diodes in the yellow range, and
the indium concentrations are greater than approximately 45%.

16. A method for manufacturing a laser diode assembly, comprising the steps of:
providing a semiconductor substrate; and
epitaxially depositing a sequence of semiconductor layers, thereby
forming at least two laser stacks, each having an active zone, and
forming at least one translucent ohmic contact,
wherein the laser stacks and the translucent ohmic contact are monolithically deposited on the semiconductor substrate,
wherein the laser stacks are connected together in an electrically conductive manner by the translucent ohmic contact, and
wherein laser diodes formed from the laser stacks form a two-dimensional structure.

17. The laser diode assembly as claimed in claim 12, wherein the active zones are configured such that the electromagnetic radiation of the laser diodes from different active zones have wavelength differences between 0.5 nm and 20 nm.

18. The laser diode assembly as claimed in claim 4, wherein the vertical gap between the laser diodes is less than 1 μm.

19. The laser diode assembly as claimed in claim 7, wherein the horizontal gap between the laser diodes is less than approximately 5 μm.

20. The laser diode assembly as claimed in claim 15, wherein the indium concentrations are between 45% and 60% for laser diodes in the red range.
